(19) United States
(12) Patent Application Publication
(10) Pub. No.: US 2015/0129421 A1
(43) Pub. Date: May 14, 2015

(54) HYBRID DEPOSITION SYSTEM

(71) Applicant: MINGDAO UNIVERSITY, Changhua County (TW)

(72) Inventors: Chi-Lung CHANG, Taichung City (TW); Wan-Yu WU, Taipei City (TW); Pin-Hung CHEN, Kaohsiung City (TW); Wei-Chih CHEN, Yunlin County (TW); Da-Yung WANG, Taichung City (TW)

(73) Assignee: MINGDAO UNIVERSITY, Changhua County (TW)

(21) Appl. No.: 14/280,657

(22) Filed: May 18, 2014

(30) Foreign Application Priority Data
Nov. 13, 2013 (TW) 102221232

(51) Int. Cl. H01J 37/34

(52) U.S. Cl. CPC H01J 37/3405; H01J 37/3417
USPC 204/298.12

(57) ABSTRACT

A hybrid deposition system includes a chamber, a pump, a gas source, a cathodic arc source, a high power impulse magnetron sputtering source and a substrate. The pump is connected with an interior of the chamber for changing a pressure of the interior of the chamber. The gas source is connected with the interior of the chamber for providing a gas into the interior of the chamber. The cathodic arc source is connected with the chamber and includes a first target disposed in the interior of the chamber. The high power impulse magnetron sputtering source is connected with the chamber and includes a second target disposed in the interior of the chamber. The substrate is disposed in the interior of the chamber and corresponded to the first target and the second target.

### RELATED APPLICATIONS

This application claims priority to Taiwan Application Serial Number 102221232, filed Nov. 13, 2013, which is herein incorporated by reference.

### BACKGROUND

1. Technical Field

The present disclosure relates to a deposition system. More particularly, the present disclosure relates to a hybrid deposition system.

2. Description of Related Art

Diamond-like carbon (DLC) films have excellent characteristics, such as high hardness, high Young's modulus, high wear resistance, high thermal conductivity, low friction coefficient and chemical inertness. When the DLC film is deposited on a surface of a high precision workpiece, the surface of the high precision workpiece can be featured with the diamond-like characteristics. Accordingly, the performance of the high precision workpiece can be enhanced.

Methods for depositing the DLC films include magnetron sputtering, cathodic arc deposition, pulse laser deposition, plasma assisted chemical vapor deposition, and plasma based ion implantation. For an example, the cathodic arc deposition is based on a principle of vacuum arc discharge. Surface atoms of a cathode target are dislodged from the cathode target and are ionized. Then the ionized surface atoms are accelerated by a negative bias voltage of an anode and are deposited on a substrate. As a result, a film is formed on the substrate. However, when the DLC films are deposited by the cathodic arc deposition, a significant number of microparticles are generated with the DLC films, and properties of the GLC films are influenced.

When the DLC films are deposited by the magnetron sputtering, the generation of microparticles can be avoided. However, a deposition rate of the magnetron sputtering is much lower than a deposition rate of the cathodic arc deposition, which is unfavorable for mass production.

Therefore, a deposition system, which can increased the deposition and can improve the properties of films, is still in demand.

### SUMMARY

According to one aspect of the present disclosure, a hybrid deposition system includes a chamber, a pump, a gas source, a cathodic arc source, a high power impulse magnetron sputtering source and a substrate. The pump is connected with an interior of the chamber for changing a pressure of the interior of the chamber. The gas source is connected with the interior of the chamber for providing a gas into the interior of the chamber. The cathodic arc source is connected with the chamber, wherein the cathodic arc source includes a first target, and the first target is disposed in the interior of the chamber. The high power impulse magnetron sputtering source is connected with the chamber, wherein the high power impulse magnetron sputtering source includes a second target, and the second target is disposed in the interior of the chamber. The substrate is disposed in the interior of the chamber and corresponded to the first target and the second target.

### BRIEF DESCRIPTION OF THE DRAWINGS

The disclosure can be more fully understood by reading the following detailed description of the embodiment, with reference made to the accompanying drawings as follows:

FIG. 1 is a schematic view of a hybrid deposition system according to one embodiment of the present disclosure;

FIG. 2 is a schematic view of a hybrid deposition system according to another embodiment of the present disclosure;

FIG. 3A is a scanning electron micrograph (SEM) image of a diamond-like carbon film according to one comparative example;

FIG. 3B is another SEM image of the diamond-like carbon film in FIG. 3A;

FIG. 4A is a SEM image of a diamond-like carbon film according to one example of the present disclosure;

FIG. 4B is another SEM image of the diamond-like carbon film in FIG. 4A;

FIG. 5A is a SEM image of a diamond-like carbon film according to another comparative example;

FIG. 5B is another SEM image of the diamond-like carbon film in FIG. 5A;

FIG. 6A is a SEM image of a diamond-like carbon film according to another example of the present disclosure;

FIG. 6B is another SEM image of the diamond-like carbon film in FIG. 6A;

FIG. 7A shows the results of Vickers hardness test of the diamond-like carbon films in FIG. 3A to FIG. 6B.

FIG. 7B shows the results of abrasion wear test of the diamond-like carbon films in FIG. 3A to FIG. 6B.

### DETAILED DESCRIPTION

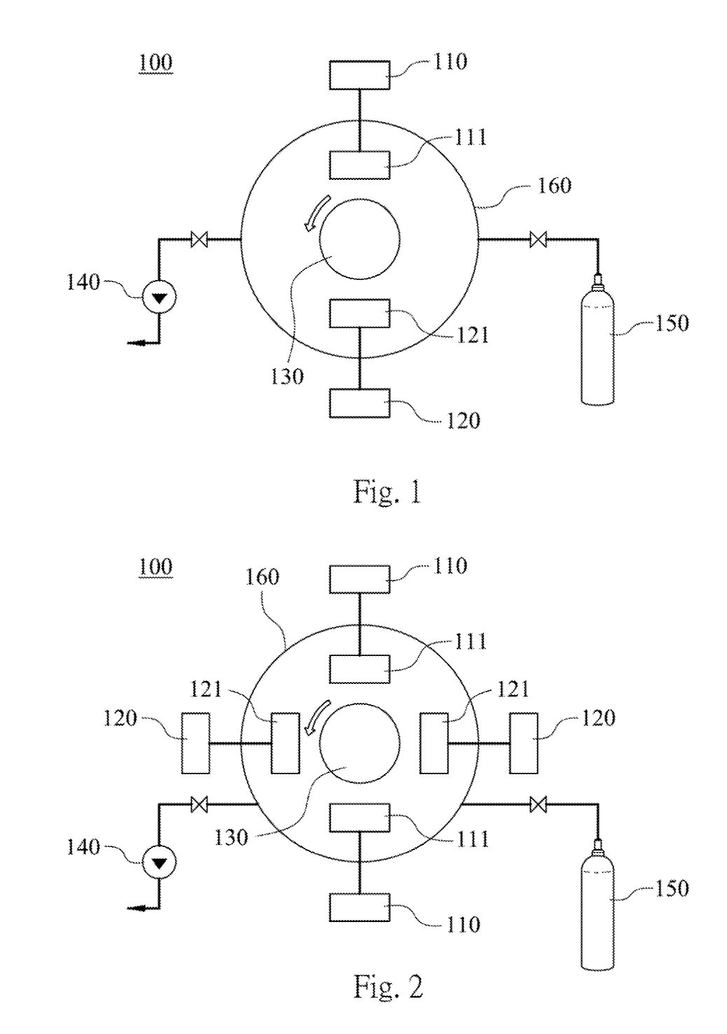

FIG. 1 is a schematic view of a hybrid deposition system 100 according to one embodiment of the present disclosure. In FIG. 1, the hybrid deposition system 100 includes a chamber 160 a cathodic arc source 110, a high power impulse magnetron sputtering source 120, a substrate 130 a pump 140 and a gas source 150.

The cathodic arc source 110 is connected with the chamber 160. The cathodic arc source 110 includes a first target 111, and the first target 111 is disposed in an interior of the chamber 160. The structure and the working principle of the cathodic arc source 110 are conventional, which will not be described in detail herein.

The high power impulse magnetron sputtering source 120 is connected with the chamber 160. The high power impulse magnetron sputtering source 120 includes a second target 121, and the second target 121 is disposed in the interior of the chamber 160. The structure and the working principle of the high power impulse magnetron sputtering source 120 are conventional, which will not be described in detail herein.

The substrate 130 is disposed in the interior of the chamber 160 and corresponded to the first target 111 and the second target 121 for enabling atoms of the first target 111 and the second target 121 to deposit on the substrate 130. In the embodiment, the substrate 130 can be rotated in a clockwise direction or in an anticlockwise direction, so that the uniformity of a

The pump 140 is connected with the interior of the chamber 160 for changing a pressure of the interior of the chamber 160. More specifically, the pump 140 can evacuate the interior of the chamber 160 to a predetermined vacuum value, so that the pressure of the interior of the chamber 160 can satisfy the work condition of the cathodic arc source 110 or the high power impulse magnetron sputtering source 120.

The gas source 150 is connected with the interior of the chamber 160 for providing a gas (not shown in FIG. 1) into the interior of the chamber 160. The gas source 150 can provide only one kind of gas or at least two kinds of gas at the same time. Furthermore, the gas provided by the gas source 150 can be a reactive gas or a neutral gas. The neutral gas can be but not limited to argon. The reactive gas can be but not limited to acetylene, oxygen or nitrogen. The aforementioned “reactive gas” refers to a gas which reacts with atoms of the first target 111 or atoms of the second target 121, i.e., atoms of the gas combine with the atoms of the first target 111 or the atoms of the second target 121 so as to generate a compound deposited on the substrate 130. In other words, the reactive gas is one of the sources of the film. The aforementioned “neutral gas” refers to a gas which does not react with the atoms of the first target 111 or the atoms of the second target 121, i.e., atoms of the gas does not combine with the atoms of the first target 111 or the atoms of the second target 121 to form a compound deposited on the substrate 130. Species of the gas, a floe rate of the gas and a pressure of the gas can be adjusted according to the material and propertied of the film.

The first target 111 and the second target 121 can be made of different materials, and a compound film can be deposited on the substrate 130 by alternately using the cathodic arc source 110 and the high power impulse magnetron sputtering source 120 (the order of using the cathodic arc source 110 and the high power impulse magnetron sputtering source 120 can be reversed according to practical demands). The aforementioned “compound film” refers to a film which is composed of at least two layers of film, and the two layers of film are made of different materials. The first target 111 and the second target 121 can be made of carbon, such as graphite. The first target 111 and the second target 121 also can be made of metal, such as titanium or chromium. In one embodiment the first target 111 can be made of carbon, and the second target 121 can be made of metal. In another embodiment, the first target 111 can be made of metal, and the second target 121 can be made of carbon. In the aforementioned two embodiments, the compound film composed at least one layer of carbon film and at least one layer of metal film can be obtained.

A conventional method for depositing the compound film quires two different kinds of deposition systems for alternately depositing different layers of film. The deposition systems need to be evacuated to a predetermined vacuum value in every deposition process, which is time-consuming. Furthermore, a high costs for purchasing the two deposition systems and a sufficient space for accommodating the two deposition systems are required. Therefore, the conventional method for depositing the compound film has drawbacks of complicated equipments, high costs and wasting time.

The hybrid deposition system 100 includes the cathodic arc source 110 and the high power impulse magnetron sputtering source 120 at the same time. On one hand, the equipments can be simplified. On the other hand, when a layer of film is deposited by using one of the sources (the sources are the cathodic arc source 110 and the high power impulse magnetron sputtering source 120), the pressure of the interior of the chamber 160 is still maintained in a vacuum condition. Therefore, the chamber 160 can be quickly adjusted to the desired vacuum condition so as to deposit another layer of film by the other of the sources (the sources are the cathodic arc source 110 and the high power impulse magnetron sputtering source 120). As a result, the time for depositing the compound film is reduced. Furthermore, when the substrate 130 is made of non-conductor, which is not allowed to deposit a film by using the cathodic arc source 110. A conductive film can be deposited on the substrate 130 by first using the high power impulse magnetron sputtering source 120 so as to change a conductivity of the substrate 130. Then the substrate 130 is allowed to deposit a film by using the cathodic arc source 110. Therefore, applications of the hybrid deposition system 100 are broadened.

The first target 111 and the second target 121 can be made of identical materials, and a single film can be deposited on the substrate 130 by alternately using the cathodic arc source 110 and the high power impulse magnetron sputtering source 120. The aforementioned “single film” refers to a film which is composed of at least two layers of film, and the layers of film are made of identical material. Furthermore, the order of using the cathodic arc source 110 and the high power impulse magnetron sputtering source 120 can be reversed according to practical demands, such as the material and the properties of the film. Compare with a single film deposited by using a single source (such as the cathodic arc source 110 or the high power impulse magnetron sputtering source 120) according to a conventional method, the properties of the single film deposited by using the two sources (the cathodic arc source 110 and the high power impulse magnetron sputtering source 120) can be improved.

FIG. 2 is a schematic view of a hybrid deposition system 100 according to another embodiment of the present disclosure. In FIG. 2, the hybrid deposition system 100 includes a chamber 160 two cathodic arc sources 110, two high power impulse magnetron sputtering sources 120, a substrate 130, a pump 140 and a gas source 150.

The two cathodic arc sources 110 are opposite to each other. Each of the cathodic arc sources 110 is connected with the chamber 160. Each of the cathodic arc source 110 includes a first target 111, and the first target 111 is disposed in an interior of the chamber 160. The structure and the working principle of the cathodic arc sources 110 are conventional, which will not be described in detail herein.

The two high power impulse magnetron sputtering sources 120 are opposite to each other. Each of the high power impulse magnetron sputtering sources 120 is connected with the chamber 160. Each of the high power impulse magnetron sputtering sources 120 includes a second target 121, and the second target 121 is disposed in the interior of the chamber 160. The structure and the working principle of the high power impulse magnetron sputtering sources 120 are conventional, which will not be described in detail herein.

According to the embodiment of FIG. 2, the hybrid deposition system 100 can flexibly change a number of the sources (10 and 120) and an arrangement of the sources (110 and 120) so as to improve the properties of the film.

According to the above description of the present disclosure, the following examples and comparative examples are provided for further explanation.

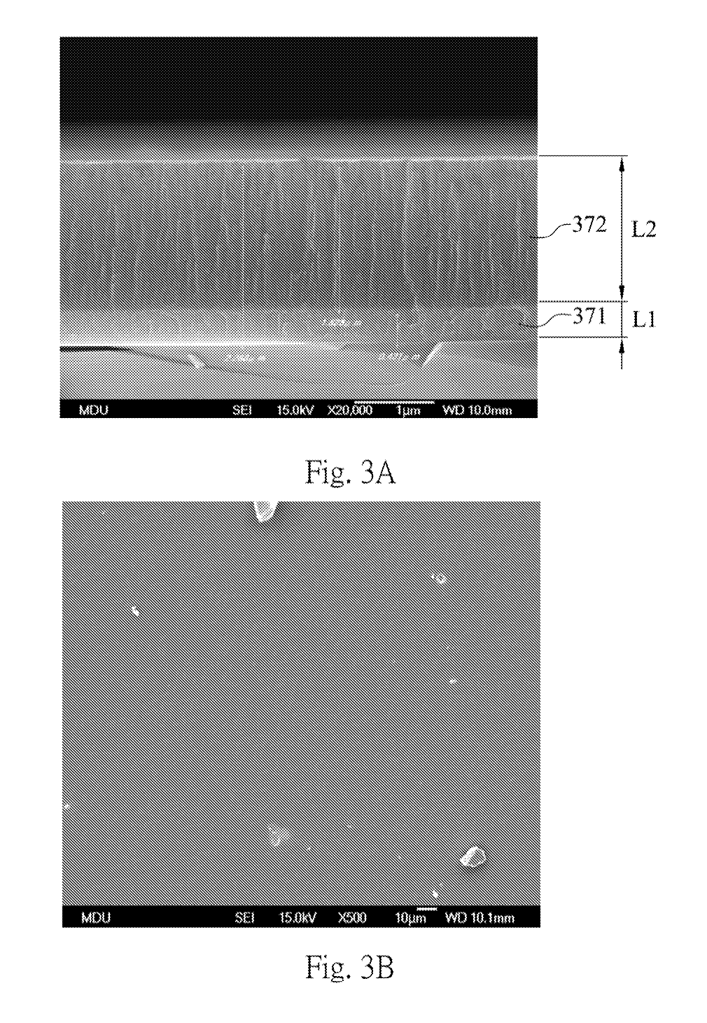

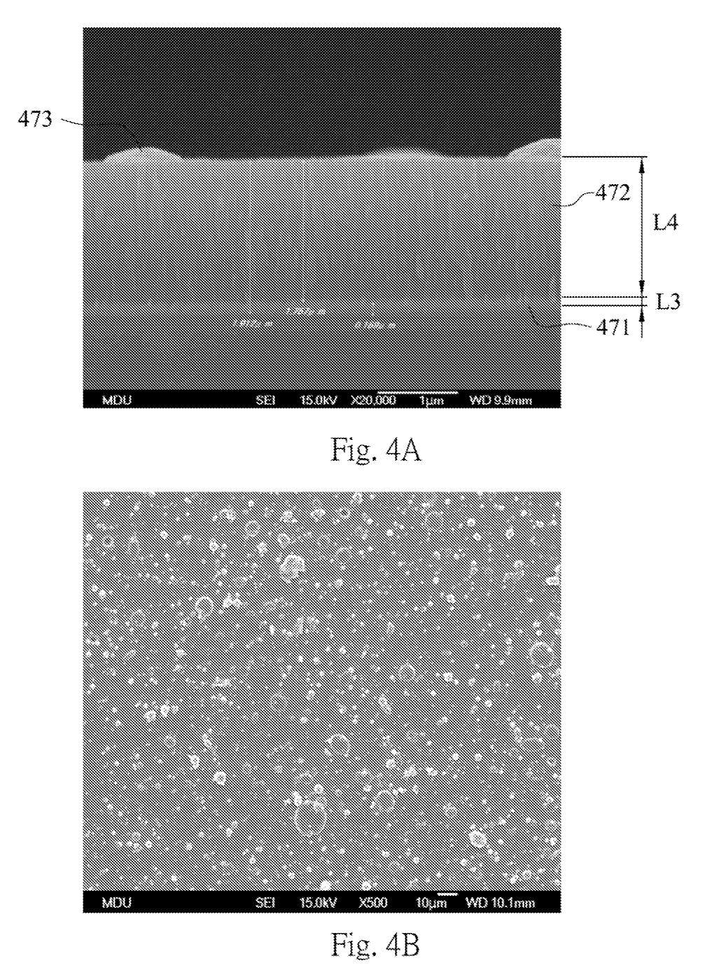

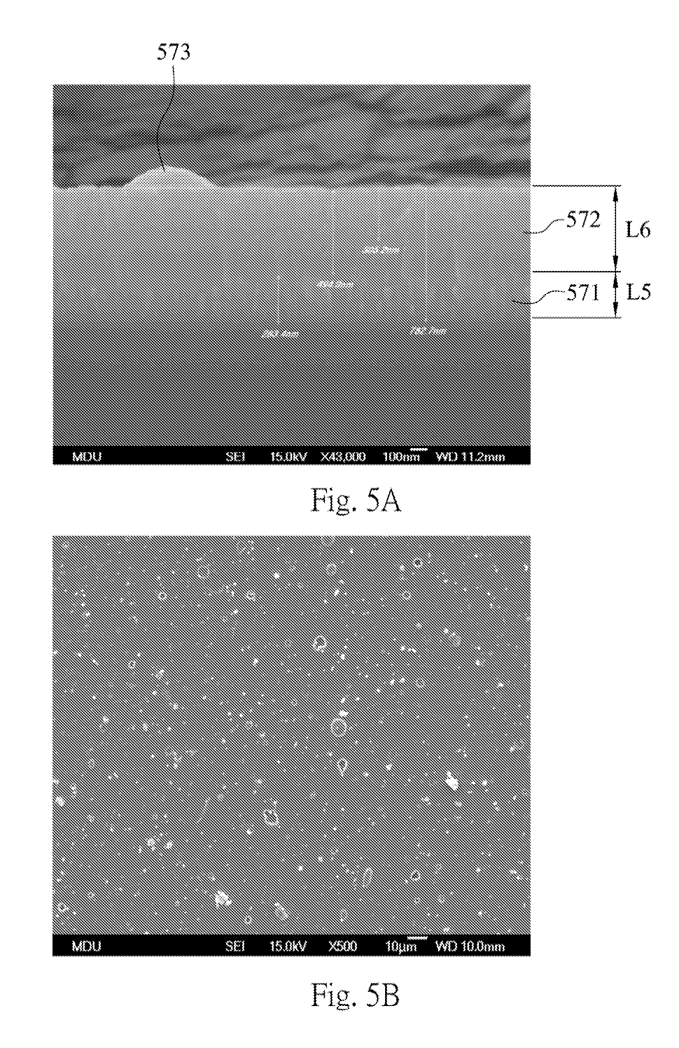

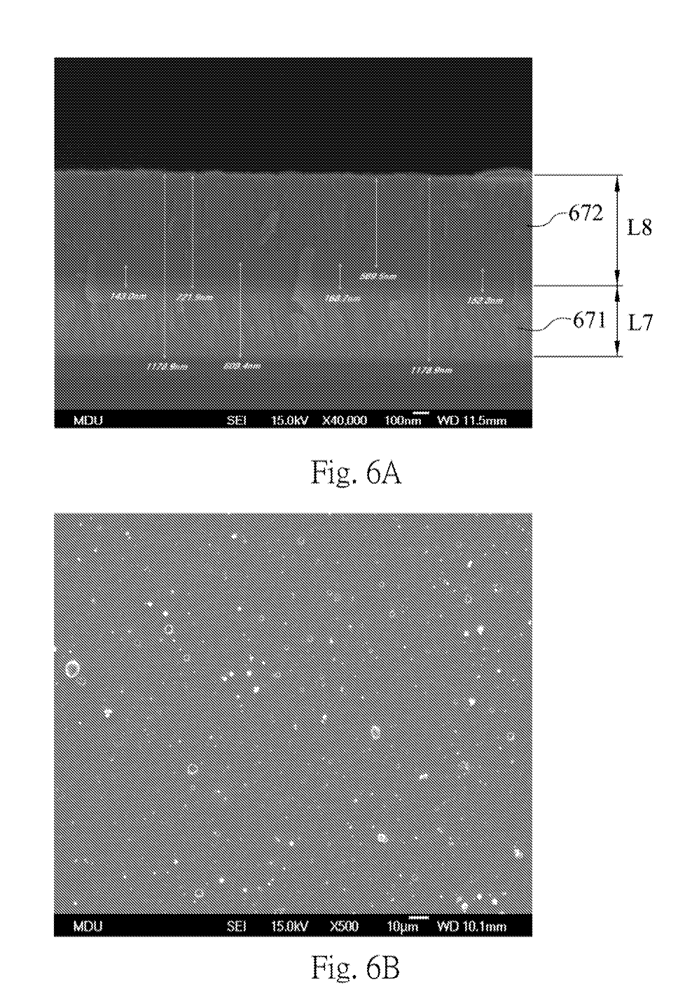

FIG. 3A is a SEM image of a diamond-like carbon film according to one comparative example. FIG. 3B is another SEM image of the diamond-like carbon film in FIG. 3A and shows a surface of the diamond-like carbon film in FIG. 3A. FIG. 4B is a SEM image of a diamond-like carbon film according to one example of the present disclosure. FIG. 4B is another SEM image of the diamond-like carbon film in FIG. 4A and shows a surface of the diamond-like carbon film in FIG. 4A. FIG. 5A is a SEM image of a diamond-like carbon film according to another comparative example. FIG. 5B is another SEM image of the diamond-like carbon film in FIG. 5A and shows a surface of the diamond-like carbon film in FIG. 5A. FIG. 6A is a SEM image of a diamond-like carbon film according to another example of the present disclosure. FIG. 6B is another SEM image of the diamond-like carbon film in FIG. 6A and shows a surface of the diamond-like carbon film in FIG. 6A.

In FIG. 3A, the diamond-like carbon film is deposited by using a high power impulse magnetron sputtering source, and a target can be made of graphite or metal, such as titanium or chromium. In the example, the target is made of titanium, A first layer 371 is deposited on a substrate, and a second layer 372 is deposited on the first layer 371. A thickness L1 of the first layer 371 is 431 nm, and the first layer 371 is made of titanium. A thickness L2 of the second layer 372 is 1828 nm, and the second layer 372 is made of titanium containing diamond-like carbon. Briefly, the diamond-like carbon film in FIG. 3A is deposited by using a single source.

In FIG. 4A, the diamond-like carbon film is deposited by using a hybrid deposition system according to the present disclosure. A first target and a second target can be made of graphite or metal, such as titanium or chromium. in the example, the first target and the second target are made of titanium. Specifically, a first layer 471 is deposited on a substrate by using a cathodic arc source. The second layer 472 is deposited on the first layer 471 by using a high power impulse magnetron sputtering source. A thickness L3 of the first layer 471 is 169 nm, and the first layer 471 is made of titanium. A thickness L4 of the second layer 472 is 1767 nm, and the second layer 472 is made of titanium containing diamond-like carbon. Furthermore, microparticles 473 are generated on the surface of the second layer 472. Briefly, the diamond-like carbon film in FIG. 4A is deposited by using two different sources.

In FIG. 5A, the diamond-like carbon film is deposited by using a cathodic arc source, and a target is made of titanium. A first layer 571 is deposited on a substrate, and a second layer 572 is deposited on the first layer 571. A thickness L5 of the first layer 571 is 283.4 nm, and the first layer 571 is made of titanium. A thickness L6 of the second layer 572 is 494.9 nm, and the second layer 572 is made of titanium containing diamond-like carbon. Furthermore, microparticles 573 are generated on the surface of the second layer 572. Briefly, the diamond-like carbon film in FIG. 5A is deposited by using a single source.

In FIG. 6A, the diamond-like carbon film is deposited by using a hybrid deposition system according to the present disclosure. A first target and a second target are made of titanium. Specifically, a first layer 671 is deposited on a substrate by using a high power impulse magnetron sputtering source. The second layer 672 is deposited on the first layer 671 by using a cathodic arc source. A thickness L7 of the first layer 671 is 456 nm, and the first layer 671 is made of titanium. A thickness L8 of the second layer 672 is 721 nm, and the second layer 672 is made of titanium containing diamond-like carbon. Briefly, the diamond-like carbon film in FIG. 6A is deposited by using two different sources.

In FIG. 3B, FIG. 4B, FIG. 5B and FIG. 6B, the diamond-like carbon film in FIG. 4B and the diamond-like carbon film in FIG. 5B have poorer surface smoothness due to the microparticles generated thereon Nevertheless, a hardness of the diamond-like carbon film in FIG. 4B is higher than that of the diamond-like carbon film in FIG. 3B, and a friction coefficient of the diamond-like carbon film in FIG. 4B is lower than that of the diamond-like carbon film in FIG. 3B. The number of the microparticles is reduced effectively in FIG. 68. Although the diamond-like carbon film in FIG. 38 has the fewest microparticles, a hardness thereof is poor, and the manufacturing process thereof is time consuming. Both the hardness relationship and the friction coefficient relationship of the diamond-like carbon films in FIG. 3A to FIG. 6B are described in detail as follows.

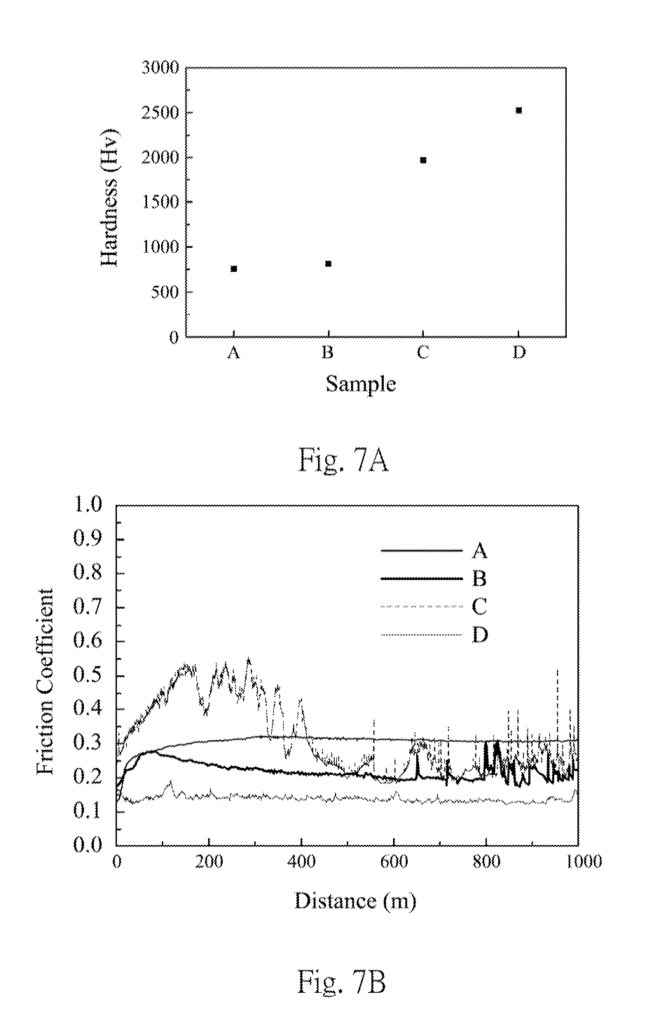

FIG. 7A shows the results of Vickers hardness test of the diamond-like carbon films in FIG. 3A to FIG. 6B. FIG. 7B shows the results of abrasion wear test (Friction Coefficient—Distance) of the diamond-like carbon films in FIG. 3A to FIG. 6B. In FIG. 7A and FIG. 78, the comparative example in FIG. 3A and FIG. 3B is represented by A, the example in FIG. 4A and FIG. 4B is represented by B, the comparative example in FIG. 5A and FIG. 5B is represented by C, and the example in FIG. 6A and FIG. 6B is represented by D. In FIG. 7A, the following relationship of hardness is satisfied: D>C>B>A, wherein a has the highest hardness. In FIG. 7B, the friction coefficient of B and the friction coefficient of D are lower, and the friction coefficient of A and the friction coefficient of C are higher, wherein D has the lowest friction coefficient.

According to FIG. 3A to FIG. 7B, when the diamond-like carbon film is deposited by using a hybrid deposition system according to the present disclosure (as shown in FIG. 6A), the first layer 671 is deposited on the substrate by using the high power impulse magnetron sputtering source, and then the second layer 672 is deposited on the first layer 671 by using the cathodic arc source, The diamond-like carbon film can have properties such as excellent surface smoothness, excellent hardness and low friction coefficient, which are better than the properties of the diamond-like carbon film deposited by using a single source.

It will be apparent to those skilled in the art that various modifications and variations can be made to the structure of the present disclosure without departing from the scope or spirit of the disclosure. In view of the foregoing, it is intended that the present disclosure cover modifications and variations of this disclosure provided they fall within the scope of the following claims.

What is claimed is:

1. A hybrid deposition system, comprising:
a chamber;
a pump connected with an interior of the chamber for changing a pressure of the interior of the chamber;
a gas source connected with the interior of the chamber for providing a gas into the interior of the chamber;
a cathodic arc source connected with the chamber, wherein the cathodic arc source comprises a first target, and the first target is disposed in the interior of the chamber;
a high power impulse magnetron sputtering source connected with the chamber, wherein the high power impulse magnetron sputtering source comprises a second target, and the second target is disposed in the interior of the chamber; and
a substrate disposed in the interior of the chamber and corresponded to the first target and the second target.

2. The hybrid deposition system of claim 1, wherein the gas provided by the gas source is a neutral gas.

3. The hybrid deposition system of claim 1, wherein the gas provided by the gas source is a reactive gas.

4. The hybrid deposition system of claim 3, wherein the reactive gas is acetylene, oxygen or nitrogen.

5. The hybrid deposition system of claim 1, wherein the first target and the second target are made of different materials, and a compound film is deposited on the substrate.

6. The hybrid deposition system of claim 1, wherein the first target and the second target are made of identical material, and a single film is deposited on the substrate.

7. The hybrid deposition system of claim 6, wherein the first target and the second target are made of carbon, and a diamond-like carbon film is deposited on the substrate.

8. The hybrid deposition system of claim 7, wherein the diamond-like carbon film is deposited by first using the high power impulse magnetron sputtering source and then using the cathodic arc source,

9. The hybrid deposition system of claim 7, wherein the gas provided by the gas source is acetylene.
